(19) United States
(12) Patent Application Publication
(10) Pub. No.: US 2007/0189072 A1
(43) Pub. Date: Aug. 16, 2007

(54) SEMICONDUCTOR MEMORY DEVICE

(75) Inventor: Shunichi Iwanari, Kyoto (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 11/672,289

(22) Filed: Feb. 7, 2007

(30) Foreign Application Priority Data
Feb. 14, 2006 (JP) 2006/037049

(51) Int. Cl. G11C 14/00

(52) U.S. Cl. 365/185.08

(57) ABSTRACT

The semiconductor memory device according to the present invention is a semiconductor memory device configured of a non-volatile memory and a volatile memory which holds a part of the data held by the non-volatile memory, and includes: j first holding units, each of which holds an address of the data, in the non-volatile memory, which corresponds to the data held in the volatile memory; and j second holding units corresponding to the j first holding units, in which each of the second holding units holds the information indicating whether or not the address held by the corresponding first holding unit is valid.

### BACKGROUND OF THE INVENTION

(1) Field of the Invention

The present invention relates to a semiconductor memory device, and in particular to a semiconductor memory device having a cache memory and a non-volatile memory having a limit on the number of read operations.

(2) Description of the Related Art

A ferroelectric memory stores data using remanent polarization of a ferroelectric film (see reference to Patent Publication 1: U.S. Pat. No. 4,873,664 and Non-Patent Publication 1: “A non-volatile IC memory—all about FRAM—”, second ed., Kogyo Chosakai Publishing Inc., Jun. 22, 1998). It is known that the magnitude of the remanent polarization of the ferroelectric film gradually decreases through the repetition of data read. When the magnitude of the remanent polarization decreases to the extent that the data read can no longer be executed, it means that the ferroelectric memory has reached the end of its useful life.

In order to prolong the lifespan of semiconductor memory devices utilizing ferroelectric memories, methods for adding more cache memories intended for ferroelectric memories have conventionally been suggested (see reference to Patent Publication 2: Japanese Laid-Open Application No. 06-215589). The semiconductor memory device according to Patent Publication 2 previously copies, into a cache memory, a part of the data in the ferroelectric memory, and reads the data from the cache memory. In the case where no data is stored in the cache memory, the semiconductor memory device reads the data from the ferroelectric memory. Thus, the number of times reading the data to the ferroelectric memory is decreased; therefore, it is possible to prolong the lifespan of the semiconductor memory device.

### SUMMARY OF THE INVENTION

However, according to the semiconductor memory device as disclosed in Patent Publication 2, the data in a ferroelectric memory is copied into a cache memory when the device is initialized (e.g. when power is turned on). This requires much time for the initialization. In other words, there is the problem that the semiconductor device equipped with a non-volatile memory such as a conventional ferroelectric memory, having a prolonged lifespan in terms of data readout, operates slowly.

An object of the present invention is to provide a semiconductor memory device which has a prolonged lifespan in terms of data readout and operates at high speed.

In order to achieve the above-mentioned object, the semiconductor memory device according to the present invention is a semiconductor memory device, including a non-volatile memory and a volatile memory which holds a part of data held in the non-volatile memory, includes: j (j≧1) first holding units, each holding an address of the data in the non-volatile memory which corresponds to the data held in the volatile memory; and j second holding units, each corresponding to each of the j first holding units and holding information indicating whether or not the address held by the corresponding first holding unit is valid.

Thus, the semiconductor memory device according to the present invention decreases the number of data readouts to the non-volatile memory by reading the data from the volatile memory holding a part of the data held by the non-volatile memory. It is therefore possible to prolong the lifespan of the semiconductor memory device. In addition, the semiconductor memory device according to the present invention can judge whether or not the address held by the first holding unit is valid based on the information held by the second holding unit. Therefore, there is no need to copy the data from the non-volatile memory when the address held by the first holding unit is initialized. As a result, it is possible to initialize the semiconductor memory device with high speed. The semiconductor memory device of the present invention therefore has a prolonged lifespan in terms of data readout and operates at high speed.

Each of the second holding units may hold information indicating that the address is invalid when the semiconductor memory device is initialized, and hold information indicating that the address is valid in the case where an address is written in the corresponding first holding unit.

Thus, the semiconductor memory device according to the present invention sets all the addresses held by the first holding unit as invalid when the device is initialized, and sets the addresses as valid after an address is newly overwritten onto one of the held addresses. Therefore, even without duplicating the data from the non-volatile memory in the initialization of the device, invalid data shall not be used by mistake.

The semiconductor memory device may further include: j first comparing units, each corresponding to each of the first holding units and comparing an externally-inputted address signal with held data held by the corresponding first holding unit, so as to judge whether or not the held data matches the address signal; j second comparing units, each corresponding to each of the second holding units and each of the first comparing units, and comparing the information held by the corresponding second holding unit with the information indicating that the address is valid, so as to judge whether or not the information match; and j judging units, each judging that the address matches the address signal in the case where a result of the comparison made by the first comparing unit indicates that the address signal matches the held data and a result of the comparison made by the corresponding second comparing unit indicates that the information match.

Thus, in the case where the second holding does not hold the information indicating that the address held by the first holding unit is valid, the inputted address signal and the address held by the first holding unit are judged to be “not matched” irrespective of the inputted address signal and the address held by the first holding unit.

Each of the first holding units may include m (m≧1) first holding elements, each element holding 1-bit data. Each of the first comparing units may include m first comparing elements, each element comparing between pieces of 1-bit data. Each one of the first holding elements may be paired with each one of the first comparing element so as to form a first holding and comparing element. Each of the second holding units may hold 1-bit data, and each of the second comparing units may compare between pieces of 1-bit data. Each one of the second holding units may be paired with each one of the second comparing units so as to form a second holding and comparing element. j×(m+1) first holding and comparing elements and second holding and comparing elements may be placed in an array.

Thus, in the semiconductor memory device of the present invention, plural comparing and holding elements, each having a holding function of 1 bit and a comparing function of 1 bit, are placed in an array. Therefore, it is possible to easily form the layout of the semiconductor memory device. Moreover, the size of the layout of the semiconductor memory device can be reduced as well.

The first holding and comparing element and the second holding and comparing element may have a same configuration.

Thus, it is possible to easily form the layout of the semiconductor memory device.

The m comparing elements included in the first comparing unit and the second comparing unit corresponding to the first comparing unit may be connected to a same wiring, and each of the judging units may judge whether or not the address matches the externally-inputted address signal, based on a signal level of the wiring.

Thus, it is possible to reduce the size of the layout of the semiconductor memory device.

Each of the first comparing elements may include: a first transistor in which the address is connected to a gate of the first transistor and the wiring is connected to a drain of the first transistor; a second transistor in which an inverting signal of the address is connected to a gate of the second transistor and the wiring is connected to a drain of the second transistor; a third transistor in which an inverting signal of the address signal is connected to a gate of the third transistor, a source of the first transistor is connected to a drain of the third transistor, and VSS is connected to a source of the third transistor; and a fourth transistor in which the address signal is connected to a gate of the fourth transistor, a source of the second transistor is connected to a drain of the fourth transistor, and VSS is connected to a source of the fourth transistor.

Thus, each of the first comparing and holding elements is configured by a circuit for extracting charges into the VSS. It is therefore possible to reduce the size of the layout of the semiconductor memory device.

The semiconductor memory device may be initialized when power of said device is turned on.

Thus, the semiconductor memory device of the present invention can operates at high speed when the power is switched on.

The semiconductor memory device may be initialized when at least one of the non-volatile memory, the volatile memory and said first holding unit is reset.

Thus, the semiconductor memory device of the present invention can operates at high speed when the device is reset.

The semiconductor memory device may further include: a selecting unit which selects at least one of the first holding unit and the second holding unit; an updating unit which updates the address held by the first holding unit selected by the selecting unit, and information held by the second holding unit selected by the selecting unit; and a controlling unit which controls, based on an externally-inputted address signal, the selection of the first holding unit and the second holding unit performed by the selecting unit.

Thus, it is possible to select arbitrary first holding unit and second holding unit, based on the signal inputted externally, and perform data writing or reading. This provides flexibility in the estimation and examination of the semiconductor memory device. In addition, it is possible to easily estimate or examine the semiconductor memory device.

The controlling unit may perform control so that the selecting unit separately selects the first holding unit and the second holding unit.

Thus, it is possible to separately write the data held in the first holding unit and the data held in the second holding unit. This provides flexibility in the estimation and examination of the semiconductor memory device. In addition, it is possible to easily estimate or examine the semiconductor memory device.

The semiconductor memory device may further include: a reading unit which reads the address held by the first holding unit and the information held by the second holding unit, wherein each of the first holding units and each of the second holding units respectively include: a first data path which allows conduction when the updating unit updates the address and the information; and a second data path which allows conduction when the reading unit reads the address and the information.

Thus, different data paths are used between the case of updating the address and information held by the holding unit and the case of reading such address and information. It is therefore possible to prevent the address and information held by the holding unit from being deconstructed, by installing, in the path for reading data, a circuit for driving and outputting the address and information held by the holding unit.

The semiconductor memory device may further include: a first comparing unit which compares the address and an externally-inputted address signal so as to judge whether or not the address matches the address signal, wherein the non-volatile memory may include a reading unit which reads the data held by the non-volatile memory. The read operation performed by the reading unit may include a first sequence and a second sequence which follows the first sequence. The first sequence may be started at the same time when said first comparing unit compares the address and the address signal. The second sequence may be operated when a result of the comparison indicates that the address matches the address signal, and may not be operated when a result of the comparison indicates that the address does not match the address signal.

Thus, the semiconductor memory device according to the present invention performs the comparison operation by the comparing unit and the read operation by the non-volatile memory in parallel. Therefore, the semiconductor memory device can perform read operation at the speed higher than the case of starting the first sequence after the comparison operation has been terminated by the first comparing unit.

The non-volatile memory may further include a writing unit which writes data into the non-volatile memory, and the writing by the writing unit may include the first sequence and the second sequence which follows the first sequence. The first sequence may be started at the same time when said first comparing unit compares the address and the address signal, and the second sequence may be operated without waiting for termination of the comparison.

Thus, the semiconductor memory device according to the present invention performs write operation into the non-volatile memory irrespective of the comparison operation. Therefore, the semiconductor memory device can perform write operation at the speed higher than the case of starting write operation after the comparison operation has been terminated.

The first sequence may be an operation of selecting a word line of the non-volatile memory, and the second sequence may be an operation of selecting a bit line of the non-volatile memory.

Thus, in the case where the result of the comparison indicates a mismatch of data in the read operation by the non-volatile memory, it is possible for the semiconductor memory device to perform read operation at a higher speed, compared with the conventional case for the duration required for the word line selection required for the operation of word line selection.

The semiconductor memory device may further include an outputting unit which has a tri-state output to output read data which is read from the non-volatile memory; and an inputting unit which inputs, to the volatile memory, the data outputted by the outputting unit, wherein control on a timing at which an output state of the outputting unit shifts from a Hi-Z output to an output of the read data and control on a timing at which the inputting unit is started up may be performed based on a same signal.

This prevents the input unit from being started up at the timing when the output state of the outputting unit is Hi-Z. In other words, it prevents continuous current from flowing into an input step of the input unit. Therefore, it is possible to reduce the amount of current consumed by the semiconductor memory device.

Note that the present invention can be realized as such a semiconductor memory device, but also as a method for reading the data into a non-volatile memory which includes, as steps, the characteristic units included in the semiconductor memory device.

The present invention can provide the semiconductor memory device which has a prolonged lifespan in terms of data readout and operates with high speed.

### FURTHER INFORMATION ABOUT TECHNICAL BACKGROUND TO THIS APPLICATION

The disclosure of Japanese Patent Application No. 2006-037049 filed on Feb. 14, 2006 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a block diagram showing an outline configuration of a semiconductor memory device according to the present invention;

FIG. 2A is a timing chart indicating the operation of the semiconductor memory device when a read hit occurs;

FIG. 2B is a timing chart indicating the operation of the semiconductor memory device when a read miss-hit occurs;

FIG. 3A is a timing chart indicating the operation of the semiconductor memory device when a write hit occurs;

FIG. 3B is a timing chart indicating the operation of the semiconductor memory device when a write miss-hit occurs;

FIG. 4 is a diagram showing in detail the configuration of a data cache unit according to the first embodiment of the present invention;

FIG. 5 is a diagram showing the configuration of a data holding/comparing element;

FIG. 6 is a timing chart indicating the comparison operation performed by the semiconductor memory device;

FIG. 7 is a timing chart indicating the initialization operation performed by the semiconductor memory device;

FIG. 8 is a diagram showing in detail the configuration of the data cache unit according to the second embodiment of the present invention;

FIG. 9 is a diagram showing in detail the configuration of the data cache unit according to a variation of the second embodiment;

FIG. 10 is a diagram showing in detail the configuration of the data cache unit according to the variation of the second embodiment;

FIG. 11 is a diagram showing the configuration of the data holding/comparing element according to the third embodiment of the present invention;

FIG. 12A is a timing chart indicating the comparison operation performed by the data holding/comparing element shown in FIG. 11 according to the third embodiment;

FIG. 12B is a timing chart indicating the reading operation of the data holding/comparing element shown in FIG. 11; and

FIG. 12C is a timing chart indicating the write operation of the data holding/comparing unit shown in FIG. 11.

### DESCRIPTION OF THE PREFERRED EMBODIMENT(S)

The embodiments of the semiconductor memory device according to the present invention will be described in detail, hereinafter, with reference to the drawings.

### First Embodiment

The semiconductor memory device according to the embodiment holds information indicating whether or not the data held in a cache memory is valid. This does not require copying the data in a non-volatile memory into the cache memory when the semiconductor memory device is initialized. It is therefore possible to perform the initialization of the device at high speed. By proceeding with the operation of reading data into the non-volatile memory in parallel with the operation of judging whether or not the data read out from the non-volatile memory is stored in the cache memory, it is possible to read data at the speed higher than the conventional cases in the case where the data to be read out is not stored in the data cache unit.

First, the outline configuration of the semiconductor memory device according to the embodiment will be described.

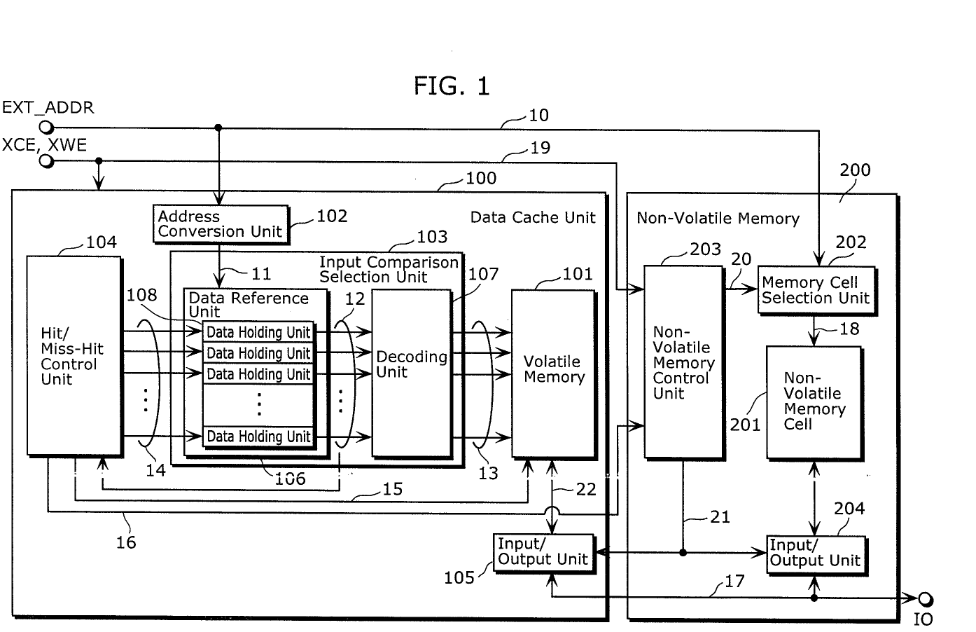

FIG. 1 is a block diagram showing the outline configuration of the semiconductor memory device. The semiconductor memory device shown in FIG. 1 is an LSI which stores data in a nonvolatile manner, and includes a data cache unit 100 and a non-volatile memory 200.

The data cache unit 100 is a cache memory which includes a volatile memory 101, an address conversion unit 102, an input comparison selection unit 103, a hit/miss-hit control unit 104 and an input/output unit 105.

The volatile memory 101 is a memory which allows an access of sufficient times, such as a static random access memory (SRAM). The volatile memory 101 holds a part of the data held by the non-volatile memory 200.

The address conversion unit 102 converts, to a data reference signal 11, an external input address signal 10 which is an address signal externally inputted, and outputs the data reference signal 11 to the input comparison selection unit 103. The external input address signal 10 is a logical address (LBA) which is requested for access from outside.

The input comparison selection unit 103 compares the data reference signal 11 outputted from the address conversion unit 102 and the held address, and outputs a memory selection signal 13 to the volatile memory 101. The input comparison selection unit 103 includes a data reference unit 106 and a decoding unit 107.

The data reference unit 106 has j (j≧1) data holding units 108. Each of the data holding units 108 holds the address in which the data stored in the non-volatile memory 200 is held. The data corresponds to the data held by the volatile memory 101. The data holding unit 108 then judges whether the held address matches the data reference signal 11 obtained by converting the external input address signal 10. The data reference unit 106 outputs, as a judgment signal 12, the information stored in the data holding unit 108 which holds the address judged as matching the data reference signal 11.

The decoding unit 107 decodes j judgment signals 12 outputted from the data reference unit 106, and outputs j memory selection signals 13.

The volatile memory 101 has memory areas for j memory selection signals 13, and is accessed according to the selected memory selection signal 13. The memory area of the volatile memory 101 is uniquely designated by a combination of j data holding units 108 and the decoding unit 107.

The hit/miss-hit control unit 104 judges whether or not the external input address signal 10 matches the data held in each of j data holding units 108, based on j judgment signals 12. The hit/miss-hit control unit 104 controls the input comparison selection unit 103, the volatile memory 101 and the non-volatile memory 200 according to the result of the judgment. A data holding unit selection signal 14 transmitted from the hit/miss-hit control unit 104 to the input comparison selection unit 103 is a signal which selects the data holding unit 108 into which the external input address signal 10 is to be newly written, in the case where the hit/miss-hit control unit 104 judges that the external input address signal 10 does not match the data held in the data holding unit 108. A volatile memory control signal 15 is a control signal which causes the volatile memory 101 to perform a desired operation in the case where the hit/miss-hit control unit 104 judges that the external input address signal 10 does not match the data in the data holding unit 108. A non-volatile memory control signal 16 is a control signal directed to the non-volatile memory 200.

The input/output unit 105 performs data input and output between the volatile memory 101 and an input/output data line 17 via a data bus 22.

The non-volatile memory 200 includes a non-volatile memory cell 201, a memory cell selection unit 202 and a non-volatile memory control circuit 21, and is a memory which stores data in a nonvolatile manner.

The non-volatile memory cell 201 is made up of plural memory cells, each having a non-volatile characteristic, and stores data into a specified address.

The memory cell selection unit 202 outputs a memory cell selection signal 18 which selects a memory cell of the non-volatile memory cell 201 corresponding to the external input address signal 10.

The non-volatile memory control unit 203 outputs a memory cell selection control signal 20 to the memory cell selection unit 202 based on an external input command signal 19 and the non-volatile memory control signal 16. The non-volatile memory control unit 203 also outputs an input/output enable signal 21 which controls the input/output of the data in the input/output unit 105 and the input/output circuit 204.

The input/output circuit 204 performs data input/output between the non-volatile memory 200 and the input/output data line 17, and has a tri-state output to output read data from the non-volatile memory 200.

Hereinafter, the operation of the semiconductor memory device according to the embodiment shall be described.

The following describes the operation when a read hit occurs, which is the case where the data of the external input address signal 10 is held in the data cache unit 100 during the read operation for reading the data held in the non-volatile memory 200.

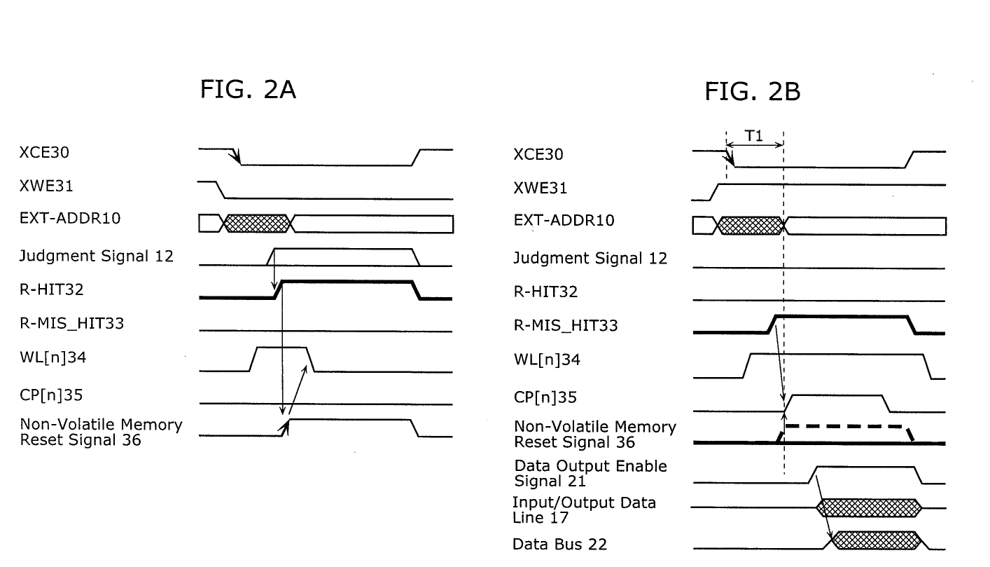

FIG. 2A is a timing chart showing the read hit operation of the semiconductor memory device according to the embodiment.

“XCE30” shown in FIG. 2A is a chip enable signal included in the external input command signal 19. When “L” level is inputted to XCE30, the data cache unit 100 and the non-volatile memory 200 fall into operation states.

“XWE31” is a signal which instructs on reading and writing of data from and to the non-volatile memory 200 and is included in the external input command signal 19.

“R-HIT32” is a read hit recognition signal included in the non-volatile memory control signal 16, and is raised to “H” level in the case where the external input address signal 10 matches the data held in the data holding unit 108 during read operation. The “R-MIS_HIT33” is a read miss-hit recognition signal included in the non-volatile memory control signal 16, and is raised to “H” level in the case where the external input address signal 10 does not match the data held in each of the data holding units 108 during read operation.

“WL[n]34” indicates the state of memory cell selection line (word line) in the selected memory cell of the non-volatile memory cell 201. “CP[n]35” indicates the state of data line (bit line) in the selected memory cell of the non-volatile memory cell 201.

A non-volatile memory reset signal 36 is a signal included in the memory cell selection control signal 20, and resets, at “H” level, the selection operation performed by the non-volatile memory cell 201 of the memory cell selection unit 202.

As shown in FIG. 2A, XCE30 is lowered to “L” level, upon which the data cache unit 100 and the non-volatile memory 200 starts the operation.

The non-volatile memory 200 starts the selection of the memory cell of the non-volatile memory cell 201 specified in the external input address signal (EXT-ADDR) 10. The operation for selecting the memory cell is performed, for example, until the memory cell selection line (WL[n]) 34 is started up. In other words, the memory cell selection unit 202 in the non-volatile memory 200 selects the memory cell selection line (WL[n]) 34 corresponding to the external input address signal 10, and raises the signal level of WL[n] 34 to “H” level.

In parallel with the operation of selecting the memory cell selection line 34, which is carried out by the non-volatile memory 200, the comparison operation described below is performed by the data cache unit 100. The address conversion unit 102 loads the external input address signal 10 and converts the loaded signal to the data reference signal 11. The data reference unit 106 compares the address held by each of the data holding units 108 and the data of the data reference signal 11 so as to judge whether or not the address matches the data. The data reference unit 106 outputs the result of the judgment as the judgment signal 12. For example, the judgment signal 12 is j signals respectively corresponding to j data holding units 108, and the judgment signal 12 corresponding to the data holding unit 108 holding the data judged as matching is raised to “H” level whereas the judgment signal 12 corresponding to the data holding unit 108 holding the data judged as not matching is lowered to “L” level. In addition, each of the data holding units 108 holds different data, and one of the judgment signals 12 out of j judgment signals 12 is raised to “H” level.

The hit/miss-hit control unit 104 judges whether the judgment signal 12 indicates hit or miss-hit. In other words, the hit/miss-hit control unit 104 judges whether or not the inputted external input address signal 10 matches (e.g. hit) or does not match (e.g. miss-hit) the address held in each of the data holding units 108. In the case where the inputted external input address signal 10 matches the address held by each of the data holding units 108, the level of the read hit recognition signal (R-HIT) 32 is raised to “H” level.

The hit/miss-hit control unit 104 outputs the non-volatile memory control signal 16 which includes the read hit recognition signal (R-HIT) 32. The non-volatile memory control unit 203 outputs, from the non-volatile memory control signal 16, a memory cell selection control signal 20 which includes the non-volatile memory reset signal 36 for releasing the selection of the non-volatile memory cell 201 by the memory cell selection unit 202. The memory cell selection unit 202 releases the selection of the non-volatile memory cell 201 based on the memory cell selection control signal 20. That is to say that the currently-selected memory cell selection line (WL[n]) 34 is made into a non-selection state. The non-volatile memory 200 falls in stand-by state for the operation of the next cycle.

The decoding unit 107 decodes the judgment signal 12 and outputs the memory selection signal 13. The corresponding data area within the volatile memory 101 is selected by the memory selection signal 13. The volatile memory 101 outputs the corresponding data to the data bus 22. The input/output unit 105 outputs the data outputted as read data to the data bus 22 via the input/output data line 17.

As has been described above, when a read hit occurs, the semiconductor memory device according to the embodiment starts up the non-volatile memory 200 by XCE30 and operates until the memory selection line (WL[n]) 34 is activated. In parallel with the operation carried out by the non-volatile memory 200, the data cache unit 100 judges whether or not the external input address signal 10 matches the address held by each of the data holding units 108. In the case where the external input address signal 10 matches the address, the data cache unit 100 reads the data from the volatile memory 101 and outputs the data to the input/output data line 17. The data cache unit 100 also cancels the read operation performed by the non-volatile memory 200.

The read miss-hit operation, which is the case, in read operation, where the data cache unit 100 does not hold the data of the external input address signal 10, shall be described hereinafter.

FIG. 2B is a timing chart showing the read miss-hit operation of the semiconductor memory device according to the embodiment. Note that the same referential marks are given to the same components as shown in FIG. 2A, and the detailed description will be omitted.

The operation of starting up the memory cell selection line (WL[n]) by the non-volatile memory 200 after “L” level has been inputted into the external input command signal 19 (XCE), and the operation of match/mismatch judging by the data reference unit 106 in the data cache unit 100 are as same as the operations carried out when a read hit occurs. The descriptions will be therefore omitted.

The result of comparing the address held by each of the data holding units 108 and the external input address signal 10 indicates “not matching”, and the hit/miss-hit control unit 104 outputs “H” level to the read miss-hit recognition signal (R-MIS_HIT) 33. The hit/miss-hit control unit 104 outputs the non-volatile memory control signal 16 which includes the read miss-hit recognition signal 33 to the non-volatile memory control unit 203.

The non-volatile memory control unit 203 starts up, using the non-volatile memory control signal 16, CP[n] 35 which is a data line for reading the data from the non-volatile memory cell 201. The non-volatile memory 200 outputs the data to the input/output data line 17 via the input/output unit 204.

Moreover, the data cache unit 100 updates the address held by the data holding unit 108 as well as the held data, in a data area of the volatile memory 101, which corresponds to the data holding unit 108. In other words, the data holding unit 108 selected by the data holding unit selection signal 14 loads the data of the data reference signal 11 and updates the address to be held. The input/output unit 105 inputs, to the volatile memory 101 via the data bus 22, the data outputted by the input/output unit 204. The area corresponding to the data holding unit 108 holding the updated data is selected, and the volatile memory 101 writes the data inputted by the input/output unit 105.

Here, control over the input/output unit 204 on the timing to shift the output state from the Hi-Z output to the output of read data from the non-volatile memory 200 and on the timing to start up the input/output unit 105 are performed based on the same signal. In other words, the control on the timing at which the input/output unit 105 loads the data outputted from the input/output unit 204 to the input/output data line 17 is performed based on the data output enable signal 21 which defines the timing to output the data from the non-volatile memory 200. As shown in FIG. 2B, the input/output unit 204 is started up by the data output enable signal 21, and the read data from the non-volatile memory 200 is outputted to the input/output data line 17. The input/output unit 105 is started up almost at the same time when the input/output unit 204 is started up, and the input/output unit 105 outputs the data of the input/output data line 17 to the data bus 22. This prevents the continuous current from flowing into an input step of the input/output unit 105 due to the starting up of the input/output unit 105 during the Hi-Z period (intermediate electric potential state) before the data is outputted from the non-volatile memory 200 to the input/output data line 17.

As described above, the semiconductor memory device according to the embodiment starts up the non-volatile memory 200 by XCE30 in the read miss-hit operation, and operates until the memory selection line (WL[n]) 34 is started up. In parallel with the operation of the non-volatile memory 200, the data cache memory unit 100 judges whether or not the external input address signal 10 matches the address held by each of the data holding units 108. In the case where the external input address signal 10 does not match the address, the semiconductor memory device starts up a data line CP[n] of the non-volatile memory 200, reads the data from the non-volatile memory 200, and outputs the data to the output data line 24. The read-out data is written into the volatile memory 101, and the corresponding address is written into the data holding unit 108.

Thus, the semiconductor memory device according to the embodiment simultaneously starts the read operation in the non-volatile memory 200 and the comparison operation in the data cache unit 100. The read operation performed in the non-volatile memory 200 continues until a memory selection line (WL[n]) is selected. Then, after the comparison operation in the data cache unit 100 has been terminated, a data line (CP[n]) is selected in the case where the result of the comparison indicates mismatch of the data (read miss-hit), whereas in the case where the result indicates matching of the data (read hit), the selection of the data line is not performed. Thus, when a read miss-hit occurs, it is possible to perform read miss-hit operation at the speed higher than the speed of the conventional semiconductor memory device since reading in the non-volatile memory 200 is already half way through (until the selection of the memory selection line). The conventional semiconductor memory device starts read operation in the non-volatile memory 200 after the hit/miss-hit judgment has been terminated. In other words, the selection of the memory selection line WL[n]34 is started after the read miss-hit recognition signal R-MIS_HIT33 is raised to “H” level. Therefore, the semiconductor memory device according to the embodiment can operate, in the read miss-hit operation, at the speed higher than the speed of the conventional device by the period T1 shown in FIG. 2B which is the time required for the selection of the memory selection line WL[n].

The following describes the write operation of writing data into the non-volatile memory 200.

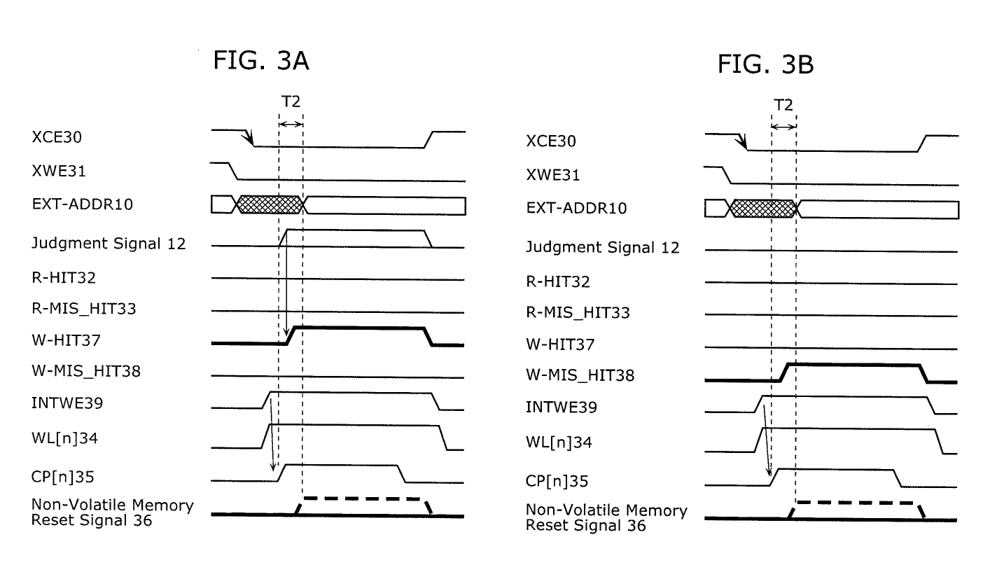

FIG. 3A is a timing chart indicating a write hit operation of the semiconductor memory device according to the embodiment. FIG. 3B is a timing chart indicating a write miss-hit operation of the semiconductor memory device according to the embodiment. Note that the same referential marks are provided for the same components as shown in FIGS. 2A and 2B, and the detailed descriptions shall be omitted.

“W-HIT37” shown in FIGS. 3A and 3B is a write hit recognition signal included in the non-volatile memory control signal 16. “W-HIT37” is raised to “H” level in the case where the external input address signal 10 matches the address held by the data holding unit 108. “W-MIS_HIT38” is a write miss-hit recognition signal included in the non-volatile memory control signal 16. “W-MIS_HIT38” is raised to “H” level in the case where the external input address signal 10 does not match the address held by each of the data holding units 108 during write operation.

“INTWE39” is an internal control signal of the non-volatile memory 200, and is a write recognition signal indicating information on whether or not write operation is being performed. “INTWE39” is raised to “H” level when the write operation is performed.

Upon the input of “L” level into XCE30, the data cache unit 100 and the non-volatile memory 200 starts the operation.

The write operation shall not be changed depending on the result of the judgment of match/mismatch between the external input address signal 10 and the address held by each of the data holding units 108, unlike the case of the read operation described above. At the point in time when write operation is recognized (INTWE39 is raised to “H” level), the operation enters the sequence which is not controlled by the non-volatile memory control signal 16. In other words, the memory cell selection signal 18 is activated disregarding the non-volatile memory control signal 16 (W-HIT37 and W-MIS_HIT38), and the write operation in the non-volatile memory 200 is proceeded.

The data cache unit 100 compares the external input address signal 10 and the address held by the data holding unit 108. In the case where the external input address signal 10 matches the address, the data cache unit 100 updates the held data, in the data area of the volatile memory 101, which corresponds to the data held in the data holding unit 108 holding the address judged as matching the data. In the case where the external input address signal 10 does not match the address, the data cache unit 100 updates both the address held by the data holding unit 108 and the held data, in the data area of the volatile memory 101, which corresponds to the data held in the data holding unit 108.

The operation of the data holding unit 108 holding the data to be updated is as same as the case of mismatch in the read operation. The data holding unit 108 selected by the data holding unit selection signal 14 loads the data of the data reference signal 11 and updates the address to be held. The data cache unit 100 selects the data area within the volatile memory 101, which corresponds to the data of the data holding unit 108 having the address updated, loads, via the input/output unit 105 and the data bus 22, the write data externally inputted to the input/output data line 17, and updates the data of the volatile memory 101.

Thus, during the write operation, the semiconductor memory device according to the embodiment writes data into the non-volatile memory 200 regardless of the hit/miss-hit judgment. In other words, the writing of data into the non-volatile memory 200 starts at the same time as the comparison operation starts in the data cache unit 100, so that the write operation is performed without waiting for the termination of the comparison operation. In this way, it is possible to perform write operation at the speed higher by the period T2 shown in FIGS. 3A and 3B, compared with the conventional case of starting the operation of writing data into the non-volatile memory 200 after the hit/miss-hit judgment has been terminated.

As described above, during the read operation, in the case where the data cache unit 100 does not have the data corresponding to a desired address (when a miss-hit occurs), the semiconductor memory device according to the embodiment can operate at high speed by operating the data cache unit 100 and the non-volatile memory 200 in parallel. During the write operation, the semiconductor memory device according to the embodiment can operate at high speed by operating the data cache unit 100 and the non-volatile memory 200 in parallel, irrespective of the result of the hit/miss-hit judgment.

Also, by adjusting the timing to start up the input/output unit 105 of the volatile memory 101 with the timing to output data from the non-volatile memory 200 when a miss-hit occurs during the read operation, it is possible to prevent continuous current caused by the start-up of the input/output unit 105 of the volatile memory 101 during the Hi-Z period of the input/output data line 17, and thereby to reduce the power consumption.

The detailed configuration and operation of the data cache unit 100 is described hereinafter.

First, the configuration of the data cache unit 100 will be described in detail.

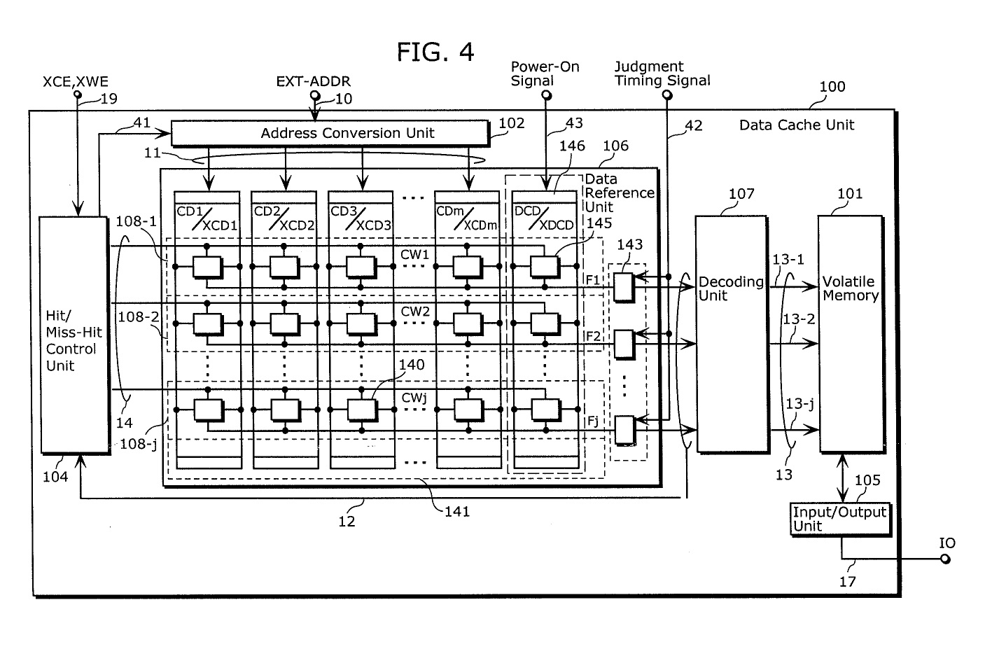

FIG. 4 is a diagram showing, in detail, the configuration of the data cache unit 100 in the semiconductor memory device shown in FIG. 1. Note that the same referential marks are provided for the same components as shown in FIG. 1, and the detailed descriptions shall be omitted.

The address conversion unit 102 converts the external input address signal 10 of m bits into a complementary signal, and outputs the signal as a data reference signal 11. The address conversion unit 102 controls m pairs of data reference lines (CD1/XCD1-CDm/XCDm) using the data reference signal 11. For example, in the case where the data of highmost bit of the external input address signal 10 indicates “1”, CD1 is raised to “H” level and XCD1 is lowered to “L” level, whereas in the case where the data of highmost bit of the external input address signal 10 indicates “0”, CD1 is lowered to “L” level and XCD is raised to “H” level.

The hit/miss-hit control unit 104 outputs, to j data holding selection lines CW1 to CWj, the data holding unit selection signal 14 of j bits, which selects the data holding unit 108 into which the address of the data reference signal 11 is written when a miss-hit occurs. In addition, the hit/miss-hit control unit 104 outputs the address control signal 41 which defines the timing at which the address conversion unit 102 loads the external input address signal 10.

The data reference unit 106 includes j data holding units 108-1 to 108-j, a data reference line processing unit 141 and j matching judgment units 143. Note that when j data holding units 108-1 to 108-j do not need to be distinguished from one another, the data holding unit shall be denoted as “data holding unit 108”.

Each of the data holding units 108 includes m (m≧1) data holding/comparing elements 140, and one data holding/comparing element 145. The m data holding/comparing elements 140 hold an address of m bits. The data holding/comparing element 145 corresponds to m data holding/comparing elements 140, and holds the information indicating whether or not the address held by m data holding/comparing elements 140 is valid. The m data holding/comparing elements 140 corresponding to the m pairs of data reference lines from CD1/XCD1 to CDm/XCDm, and the data holding/comparing element 145 corresponding to the data reference line DCD/XDCD are selected by the common data holding unit selection lines CW1 to CWj.

The data reference line processing unit 141 performs processing such as pre-charging of the data reference lines CD1/XCD1 to CDm/XCDm.

The matching judgment unit 143 judges whether or not the address held by each of the data holding units 108 matches the external input address signal 10, based on the signal level of matching judgment nodes F1 to Fj at the timing of a judgment timing signal 42, and outputs the judgment signal 12 indicating the result of the judgment. Each of the matching judgment units 143 is connected to one of the matching judgment nodes F1 through Fj.

The decoding unit 107 generates, based on the judgment signal 12, j memory selection signals 13-1 to 13-j, each of which selects a data area of the volatile memory 101 corresponding to each of the data holding units 108. Note that in the case where the memory selection signals 13-1 to 13-j do not need to be distinguished from one another, the memory selection signal shall be denoted as “memory selection signal 13”.

The data holding/comparing element 140 and the data holding/comparing element 145 held data of 1 bit and are elements which compare the held data and the data inputted to the corresponding data reference line. As shown in FIG. 4, j×(m+1) data holding/comparing elements 140 and data holding/comparing elements 145 are placed in an array.

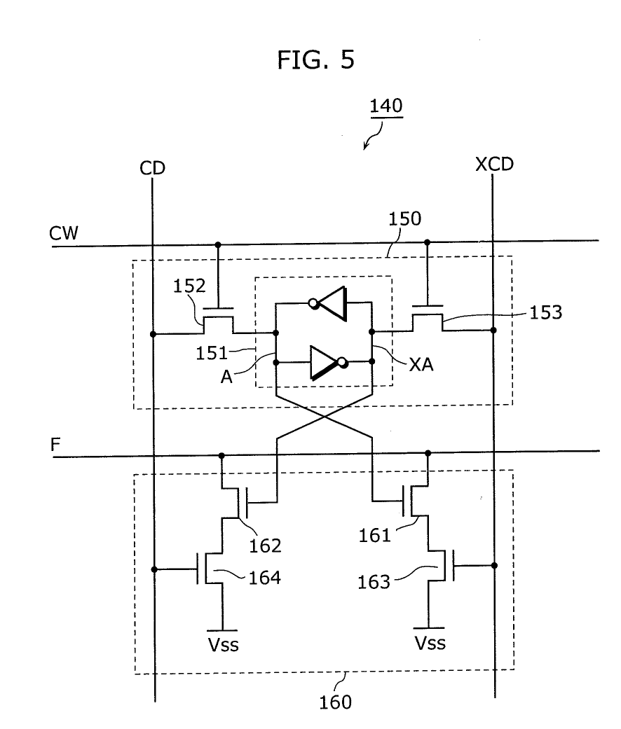

FIG. 5 is a diagram showing the configuration of the data holding/comparing element 140. Note that the data holding/comparing element 145 has the same configuration as that of the data holding/comparing element 140.

As shown in FIG. 5, the data holding/comparing element 140 includes a data holding unit 150 which holds data of 1 bit, and a comparison unit 160 which compares between plural pieces of 1-bit data. Note that, in FIG. 5, CW indicates a data holding unit selection line, among the data holding unit selection lines CW1 to CWj, which corresponds to the data holding/comparing element 140. F denotes a matching judgment node, among the matching judgment nodes F1 to Fj, which corresponds to the data holding/comparing unit 140. CD/XCD indicates the data reference line, among the data reference lines CD1/XCD1 to CDm/XCDm and DCD/XDCD, which corresponds to the data holding/comparing element 140. “A” denotes the data held in the data holding/comparing element 140, while “XA” denotes an inverting signal of the data held in the data holding/comparing element 140. For example, in the case where the data holding/comparing element 140 holds data “1”, the signal level of A is at “H” level and the signal level of XA is at “L” level. In the case where the data holding/comparing element 140 holds data “0”, the signal level of A is at “L” level and the signal level of XA is at “H” level.

The holding unit 150 includes a latch unit 151, and transistors 152 and 153. The latch unit 151 is a latch circuit which holds 1-bit-data. The transistors 152 and 153 are, for instance, n-type MOSFETs. In the case of writing data into the data holding/comparing element 140, the data holding unit selection line CW is raised to “H” level, the transistors 152 and 153 are switched on, and the latch unit 151 loads the data of the data reference line CD/XCD.

The comparison unit 160 includes transistors 161 to 164. The transistors 161 to 164 are, for example, n-type MOSFETS.

In the transistor 161, an address A held by the latch unit 151 is connected to the gate of the transistor 161, and a matching judgment node F is connected to the drain of the transistor 161. In the transistor 162, an inverting signal XA of the address held by the latch unit 151 is connected to the gate of the transistor 162, and the matching judgment node F is connected to the drain of the transistor 162. In the transistor 163, the data reference line XCD to which an inverting signal of the external input address signal 10 is applied is connected to the gate of the transistor 163, and the source of the transistor 161 is connected to the drain of the transistor 163, and VSS is connected to the source of the transistor 163. In the transistor 164, the data reference line CD to which the external input address signal 10 is applied is connected to the gate of the transistor 164, the source of the transistor 162 is connected to the drain of the transistor 164, and VSS is connected to the source of the transistor 164.

In the comparison operation, the matching judgment node F is pre-charged by VDD. In the case where the data A/XA held by the holding unit 150 matches the data inputted to the data reference line CD/XCD, one of the transistors 161 and 163 is switched on, and the other is switched off. Likewise, one of the transistors 162 and 164 is switched on and the other is switched off. In the case where the data match with each other, the pre-charged level of the matching judgment node F is maintained. In the case where the data A/XA held by the holding unit 150 does not match the data inputted by the data reference line CD/XCD, both of the transistors in one of a pair of the transistors 161 and 163 and a pair of the transistors 162 and 164 are switched on and both of the transistors in the other pair are switched off. The matching judgment node F is connected to VSS (GND) and the level is lowered to “L” level. For example, in the case where data “1” is held (e.g. A indicates “H” level and XA indicates “L” level), when data “1” is inputted into the data reference line CD/XCD (“H” level is inputted into CD and “L” level is inputted into XCD), the transistor 161 is switched on since A indicates “H” level and the transistor 163 is switched off since XCD is at “L” level. As a result, the matching judgment node F is not connected to VSS in the paths of the transistors 161 and 163. Also, the transistor 162 is switched off since XA indicates “L” level, and the transistor 164 is switched on since CD is at “H” level. Consequently, the matching judgment node F is not connected to VSS in the paths of the transistors 162 and 164. Therefore, in the case where the data A/XA held by the holding unit 150 matches the data inputted by the data reference line CD/XCD, the level of the matching judgment node F is maintained to be “H” level. In contrast, in the case where data “1” is held (e.g. A indicates “H” level and XA indicates “L” level), when data “0” is inputted into the data reference line CD/XCD (“L” level is inputted into CD and “H” level is inputted into XCD), the transistor 161 is switched on since A indicates “H” level and the transistor 163 is switched on since XCD is at “H” level. As a result, the matching judgment node F is connected to VSS in the paths of the transistors 161 and 163. In other words, in the case where the data A/XA held by the holding unit 150 does not match the data inputted by the data reference line CD/XCD, the level of the matching judgment node F lowered to “L” level.

To the matching judgment node F, m data holding/comparing elements 140 and one data holding/comparing element 145 which are included in the data holding unit 108 are connected. When only one piece of data out of the data held by the m data holding/comparing elements 140 and the data holding/comparing element 145 does not match the external input address signal 10, the matching judgment node F is lowered to “L” level. Only in the case where the respective piece of data held by the m data holding/comparing elements 140 and the data holding/comparing element 145 matches the external input address signal 10, the matching judgment node F keeps “H” level. Therefore, in the case where the result of comparing the external input address signal 10 and the data held by each of the data holding/comparing elements 140 and the result of comparing the external input address signal 10 and the data held by the data holding/comparing element 145 both indicates the matching of the data, the matching judgment unit 143 judges that the address held by the data holding unit 108 has matched the external input address signal 10.

As described above, the semiconductor memory device according to the embodiment has the configuration in which the data holding/comparing elements 140 and 145, each element having the holding unit 150 and the comparison unit 160, are placed in an array.

The comparison unit 160 in the respective data holding/comparing elements 140 and 145 only has a circuit for extracting the charge of the matching judgment node F, and m data holding/comparing elements 140 and one data holding/comparing element 145 in each data holding unit 108 are connected to the same matching judgment node F. With such a configuration, the size of the layout of the data cache unit 100 can be reduced. Also, plural data holding/comparing elements 140 and 145 of the same layout are placed. It is therefore possible to easily form the layout even in the case where the memory capacity of the data cache unit 100 is changed or the like.

Hereinafter, the comparison operation carried out by the data cache unit 100 shall be described in detail.

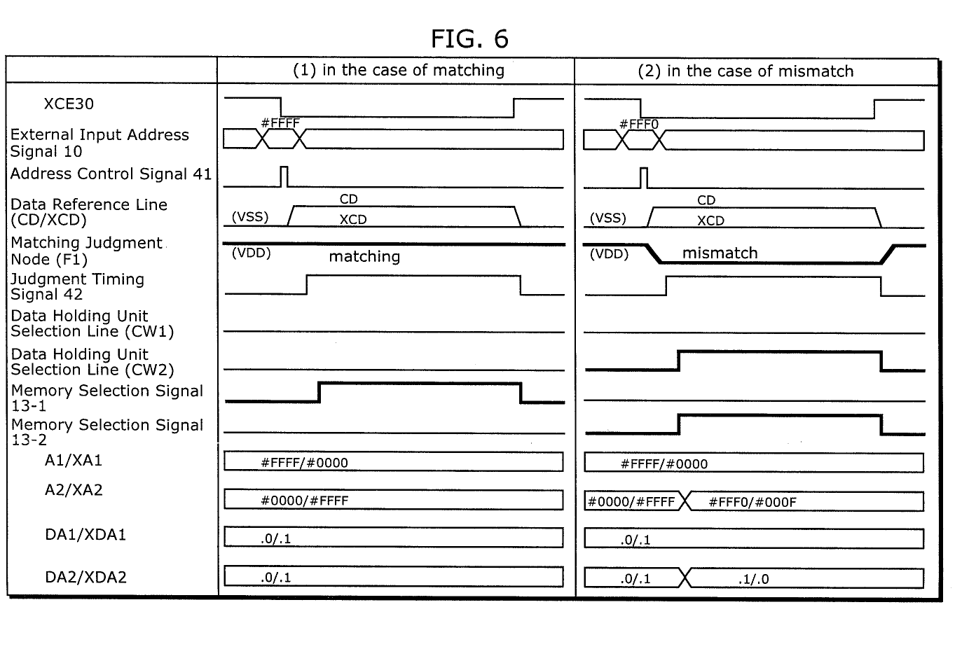

(1) in FIG. 6 is a timing chart in the case where the result of the comparison for judgment indicates matching of the data. Note that, in (1) in FIG. 6, the external input address signal 10 and the address held by the data reference unit 106 is of 16 bits. To simplify the description, the data held in each address in the volatile memory 101 and the non-volatile memory 200 is of 1 bit.

A1/XA1 shown in (1) in FIG. 6 is an address of 16 bits held by the data holding unit 108-1, while A2/XA2 is an address of 16 bits held by the data holding unit 108-2.

DA1/XDA1 denotes data held in an area in the volatile memory 101, which corresponds to the data holding unit 108-1. DA2/XDA2 denotes data held in an area in the volatile memory 101, which corresponds to the data holding unit 108-2.

The hit/miss-hit control unit 104 generates the address control signal 41 due to the rise of the level of XCE30. The address conversion unit 102 loads the external input address signal 10 at the timing of the address control signal 41, and outputs the data reference signal 11. As shown in (1) in FIG. 6, the external input address signal 10 is of 16 bits and the address conversion unit 102 loads the data “FFFF”, for instance. The address conversion unit 102 outputs the signal corresponding to the data “FFFF” to the data reference lines CD1/XCD1 to CD16/XCD16. In other words, “H” level is outputted to the data reference lines CD1 to CD16, while “L” level is outputted to the data reference lines XCD1 to XCD16.

The data reference lines CD1/XCD1 to CD16/XCD16 are pre-charged by VSS in stand-by state, and the pre-charging is stopped at the timing of the address control signal 41.

The matching judgment nodes F1 to F16 are pre-charged by VDD in stand-by state.

When the level of the data reference lines CD1/XCD1 to CD16/XCD16 come to be at the signal level corresponding to the level of the external input address signal 10, each of the data holding/comparing elements 140 compares the held address and the external input address signal 10. In the data holding unit 108-1, since the held address A1/XA1 and the external input address signal 10 both indicate “FFFF”, the matching judgment node F1 keeps the level of VDD. Also, the address held by each of the data holding unit 108-2 to 108-j does not match the external input address signal 10; therefore, the level of the respective matching judgment nodes F2 to Fj is lowered to “L” level.

The matching judgment unit 143 judges whether or not the external input address signal 10 matches the address held by each of the data holding units 108 based on the matching judgment nodes F1 to Fj at the timing of the judgment timing signal 42. In other words, in the case where each of the matching judgment nodes F1 to Fj is at “H” level, the matching judgment unit 143 judges that the external input address signal 10 matches the address, whereas in the case where each of the matching judgment nodes F1 to Fj is at “L” level, the matching judgment unit 143 judges that the external input address signal 10 does not match the address. The matching judgment unit 143 then outputs the result of the judgment as the judgment signal 12.

The decoding unit 107 outputs the memory selection signal 13 based on the judgment signal 12. Since the address held by the data holding unit 108-1 matches the external input address signal 10, “H” level is outputted to the memory selection signal 13-1 corresponding to the data holding unit 108-1. Also, “L” level is outputted to the memory selection signals 13-2 to 13-j.

An area in the volatile memory 101 is selected based on the memory selection signal 13. In other words, the area, in the volatile memory 101, which is specified by the memory selection signal 13-1 is selected, and the data DA1/XDA1 is read out.

(2) in FIG. 6 is a timing chart in the case where the result of judgment made by the semiconductor memory device indicates mismatch of the data. Note that any of the data A3/XA3 to Aj/XAj held by each of the data holding units 108-3 to 108-j shall not indicate “FFF0/000F”.

The hit/miss-hit control unit 104 generates the address control signal 41 due to the rise of XCE30. The address conversion unit 102 loads the external input address signal 10 at the timing of the address control signal 41, and outputs the data reference signal 11. The address conversion unit 102 outputs the signal corresponding to the data “FFF0” to each of the data reference lines CD1/XCD1 to CD16/XCD16. For example, “H” level is outputted to the data reference lines CD1 to CD12 and the XCD13 to XCD16, while “L” level is outputted to the data reference lines CD13 to CD16 and XCD1 to XCD12.

When the data reference lines CD1/XCD1 to CD16/XCD16 come to be at the signal level corresponding to the level of the external input address signal 10, each of the data holding/comparing elements 140 compares the external input address signal 10 and the held address. Since the address held by each of the data holding units 108-1 to 108-j does not match the external input address signal 10, the level of each of the matching judgment nodes F1 to Fj changes to “L” level. The matching judgment unit 143 outputs, as the judgment signal 12, the result of the judgment indicating the mismatch of the data, based on the matching judgment nodes F1 to Fj.

In the case where the result of the judgment indicates the mismatch of the data, the hit/miss-hit control unit 104 raises, to “H” level, the level of one of the data holding unit selection lines CW1 to CWj generated from the internal address. For example, CW2 is raised to “H” level as shown in (2) in FIG. 6. The data of the data reference lines CD1/XCD1 to CD16/XCD16 is written in sixteen data holding/comparing elements 140 of the data holding unit 108-2. In other words, the data A2/XA2 stored in the data holding unit 108-2 becomes “FFF0/000F”.

When “FFF0/000F” is held as the data A2/XA2 stored in the data holding unit 108-2, the level of the memory selection signal 13-2 corresponding to the data holding unit 108-2 is raised to “H” level, and the corresponding data area in the volatile memory 101 is selected. The corresponding data area of the volatile memory 101 is updated to hold the data read by the non-volatile memory 200. For instance, in the case where the data read by the non-volatile memory 200 indicates “1”, DA2/XDA2 is updated to “1/0”.

Hereinafter, the initialization operation performed by the semiconductor memory device according to the embodiment will be described.

In the case where the address held by the data holding/comparing element 140 is uncertain, the semiconductor memory device may cause errors when being accessed in such a condition. For example, when the power is turned on, the address held by the data holding/comparing element 140 becomes uncertain. It is therefore necessary to initialize the semiconductor memory device in order to set correct data in the data holding/comparing element 140.

The semiconductor memory device according to the embodiment holds, in the data holding/comparing element 145, the information indicating whether or not the data held in the data cache unit 100 is valid. During the initialization operation, the data cache unit 100 writes, in the data holding/comparing element 145, the information indicating that the data held in the data cache unit 100 is invalid. After the data held in the data cache unit 100 has been updated, the data cache unit 100 writes, into the data holding/comparing element 145, the information indicating that the held data is valid. Thus, in the initialization, the data in the non-volatile memory 200 does not need to be copied in the data cache unit 100, and therefore, the initialization can be performed at high speed.

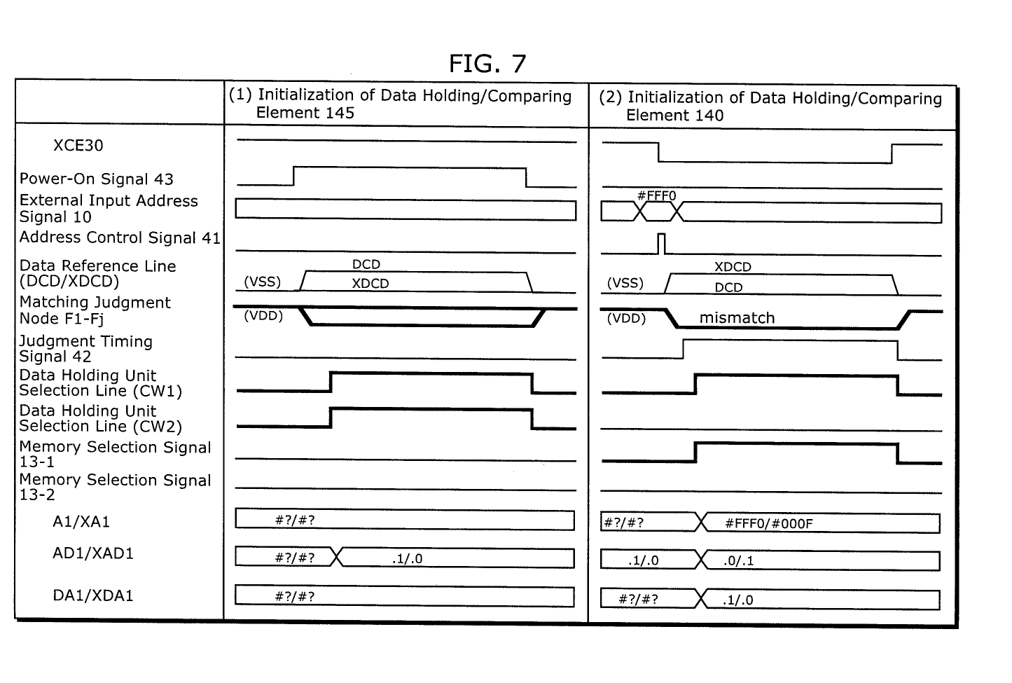

FIG. 7 is a timing chart showing the initialization of the semiconductor memory device according to the embodiment. (1) in FIG. 7 is a timing chart showing the operation of initializing the data holding/comparing element 145.

“AD1/XAD1” shown in FIG. 7 is data held by the data holding/comparing element 145 of the data holding unit 108-1.

By the power-on signal 43 which is a signal indicating that the power is turned on, the data reference line processing unit 146 applies VDD/VSS (“1/0”) to the data reference line DCD/XDCD both of which have been pre-charged by VSS. The level of each of the data holding unit selection lines CW1 to CWj is raised to “H” level. This allows the data “1/0” to be held by j data holding/comparing elements 145.

The address control signal 41 and the judging timing signal 42 are not activated (retains the level of VSS), the levels of the data reference lines CD1/XCD1 to CD16/XCD16 are maintained to be the level of VSS as has been pre-charged, and the matching judgment function is stopped.

As described above, “1/0” is held in the data AD1/XAD1 to ADj/XADj held by each of the data holding/comparing elements 145, and the initialization operation is terminated.

(2) in FIG. 7 is a timing chart showing the comparison operation after the initialization operation has been terminated.

During the access time after the initialization operation is completed, the data reference line processing unit 146 applies VSS/VDD (“0/1”), which is inverse data of the data applied in the initialization operation, to the data reference line DCD/XDCD. The data holding/comparing element 145 judges whether or not the held data matches the data (“0/1”) indicating the information which indicates that the data held by the data holding unit 108 is valid. Due to the initialization operation, the data held by each of the data holding/comparing elements 145 indicates “1/0”; therefore, the data held by the data holding/comparing element 145 does not match the data of the data reference line DCD/XDCD. Thus, the level of each of the matching judgment nodes F1 to Fj is lowered to “L” level, and the matching judgment unit 143 outputs the result of the judgment indicating the mismatch of the data. In other words, after the initialization operation, the matching judgment is performed irrespective of the external input address signal 10 and the data held by each of the data holding units 108.

After the judgment indicating the mismatch of the data is made, the same operation as in the case of mismatch described above follows, and the held data A1/XA1 in the data holding unit 108-1 selected by the data holding unit selection line CW1, and the data area in the volatile memory 101 selected by the memory selection signal 13-1 corresponding to the data holding unit 108-1 are updated. In other words, the data A1/XA1 held by the data holding unit 108-1 is updated to “FFF0/000F”, as shown in (2) in FIG. 7. In the case where the data that has been held in the corresponding address in the non-volatile memory 200 indicates “1”, the data DA1/XDA1, in the data area of the volatile memory 101, which corresponds to the data holding unit 108-1 is updated to “1/0”.

At the same time when the data A1/XA1 held by the data holding unit 108 is updated, the data AD1/XAD1 held by the data holding/comparing element 145 corresponding to the data holding unit 108-1 is updated to the data “0/1” which is applied to the data reference line DCD/XDCD.

With this, the data holding/comparing element 145 of the data holding unit 108-1, holding the updated data, holds the data judged as matching the data of the data reference line DCD/XDCD. Therefore, the judgment resulting in mismatch of data shall not be subjected to the held data of the data holding/comparing element 145. In other words, the result of the comparison made by the data holding/comparing element 140 is reflected on the judgment of the matching judgment unit 143. Hereinafter, the same operation follows until all the data holding units 108 are initialized.

In this way, the address held by the data holding unit 108 is made invalid by the data held by the data holding/comparing element 145 until the address held by the data holding unit 108 and the data held in the corresponding area in the volatile memory 101 are updated (e.g. until valid data is written thereto), and after an address is written in the data holding unit 108, the address held by the data holding unit 108 is made valid.

As described above, the semiconductor memory device according to the embodiment holds, in the data holding/comparing element 145, the information indicating whether or not the data held by the data holding unit 108 is valid. The data holding/comparing element 145 holds, at the time of initialization, the information indicating that the address held by the data holding unit 108 is invalid. Thus, in read operation after the initialization operation, the result of the comparison between the external input address signal 10 and the address held by the data holding unit 108 indicates the mismatch of the data, and invalid data shall not be used by mistake. In the case where an address is written in the data holding unit 108, the corresponding data holding/comparing element 145 holds the information indicating that the address held by the data holding unit 108 is valid. Hereinafter, the data holding unit 108 having the address updated operates normally.

In this way, the semiconductor memory device according to the embodiment only writes, as the initialization operation, the information into the data holding/comparing element 145. The information indicates that the data held by the data holding unit 108 is invalid. It is therefore possible to perform the initialization operation at the speed higher than the conventional case of duplicating the data in the non-volatile memory 200 into the volatile memory 101.

Moreover, with the semiconductor memory device according to the embodiment, the number of times reading data from the non-volatile memory 200 is reduced by reading a part of the data of the non-volatile memory 200 from the volatile memory 101. As a result, the lifespan of the semiconductor memory device can be prolonged.

The semiconductor memory device according to the embodiment has the configuration in which plural data holding/comparing elements 140 and 145, each element including the holding unit 150 and the comparison unit 160, are placed in an array. The comparison unit 160 in each of the data holding/comparing elements 140 and 145 has only a circuit for extracting the charge of the matching judgment node F, and m data holding/comparing elements 140 and one data holding/comparing element 145 of each of the data holding units 108 are connected to the same matching judgment node F. With such a configuration, the size of the layout of the data cache unit 100 can be reduced. In addition, plural data holding/comparing elements 140 and 145 of the same layout are placed. It is therefore possible to easily form the layout even in the case where the memory capacity of the data cache unit 100 is changed or the like.

During the read operation (when a miss-hit occurs), in the case where the data cache unit 100 does not have the data corresponding to a desired address, the semiconductor memory device according to the embodiment can operate at high speed by operating the data cache unit 100 and the non-volatile memory 200 in parallel. During the write operation, the semiconductor memory device according to the embodiment can operate at high speed by operating the data cache unit 100 and the non-volatile memory 200 in parallel, irrespective of the result of the hit/miss-hit judgment.

Also, by adjusting the timing to start up the input/output unit 105 of the volatile memory 101 with the timing to output data from the non-volatile memory 200 when a miss-hit occurs during the read operation, it is possible to prevent continuous current caused by the start-up of the input/output unit 105 of the volatile memory 101 during the Hi-Z period of the input/output data line 17, and thereby to reduce the power consumption.

As has been described above, the semiconductor memory device according to the embodiment of the present invention is described; however, the present invention is not limited to this embodiment.

For example, it is described that the external input address signal 10 and the data held by the data holding unit 108 is of 16 bits. However, the present invention is not limited to this example.

According to the description, the data that is read from the non-volatile memory 200 as well as the data held by the volatile memory 101 is of 1 bit. The present invention, however, is not limited to this example. For example, data may be held in the non-volatile memory 200 and the volatile memory 101 in units of bytes or in units of words.

Also, it is described in the embodiment that in the case of mismatch, the address of the data holding unit 108-2 is updated; however, an address of other data holding unit may be updated.

The embodiment describes that, in the initialization of the data holding/comparing element 145, CW1 to CWj are selected and data is simultaneously set in all of the data holding/comparing elements 145. However, the present invention is not limited to this. For example, data may be set through time-sharing per each data holding/comparing element 145 or per plural data holding/comparing elements 145.

According to the embodiment, the initialization of the data holding/comparing element 145 is performed when the power is turned on. The present invention, however, is not limited to this case. For example, the memory may be reset, by the system, without switching off the power, and the initialization operation may be performed during such a resetting operation. For instance, the initialization operation may be performed during the operation of resetting at least one of the non-volatile memory 200, the volatile memory 101 and the data reference unit 106.

### Second Embodiment

The semiconductor memory device according to the second embodiment can arbitrarily change the address held by the data holding unit 108 by setting a test circuit.

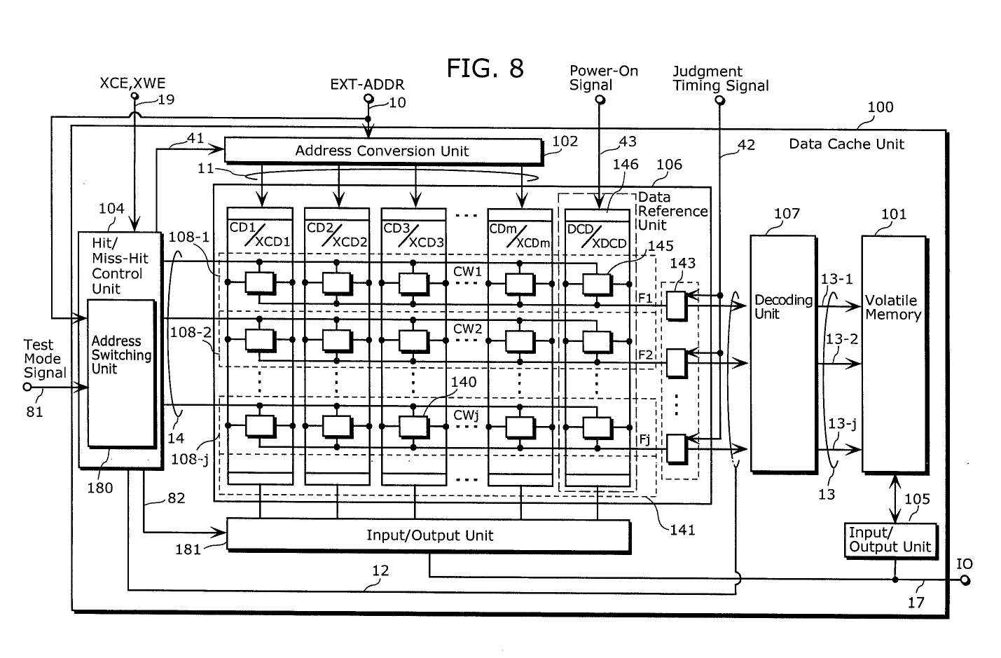

FIG. 8 is a diagram showing the configuration of the data cache unit 100 of the semiconductor memory device according to the second embodiment. Please note that the same referential marks are provided for the same components as shown in FIG. 4, and the detailed description shall be omitted.

The semiconductor memory device shown in FIG. 8 is different from the semiconductor memory device according to the first embodiment in that the device of the present embodiment includes an input/output unit 181, and an address switching unit 180 in the hit/miss-hit control unit 104.

The address switching unit 180 controls the selection of the data holding unit 108 in the hit/miss-hit control unit 104, based on the external input address signal 10 and a test mode signal 81 which is externally inputted and indicates that the operation is in a test mode. In other words, the address switching unit 180 controls the generation of the data holding unit selection signal 14.

The input/output unit 181 inputs or outputs the data between the input/output data line 17 and the data reference line processing unit 141, based on a test input/output control signal 82.

With the semiconductor memory device according to the present embodiment, it is possible to select an arbitrary data holding unit 108 by raising, by the address switching unit 180, the level of an arbitrary one of the data holding unit selection lines CW1 to CWj to “H” level, using the external input address signal 10 and the test mode signal 81. In addition, it is possible to arbitrarily change the data held by the data holding/comparing elements 140 and 145 by loading an externally-inputted signal via the input/output data line 17 and the input/output unit 181, and outputting the corresponding signal to the data reference lines CD1/XCD1 to CD16/XCD16 as well as DCD/XDCD. Furthermore, it is possible to externally output the data held by the data holding/comparing element 140 and 145 via the input/output unit 181 and the input/output data line 17 (read operation in the case of testing).

Thus, with the semiconductor memory device according to the embodiment, it is possible to enhance the flexibility in the examination and estimation of the device.

Note that, in the embodiment, the address switching unit 180 is equipped in the hit/miss-hit control unit 104, but it may be placed between the data holding/comparing element 140 and the data holding/comparing element 145.

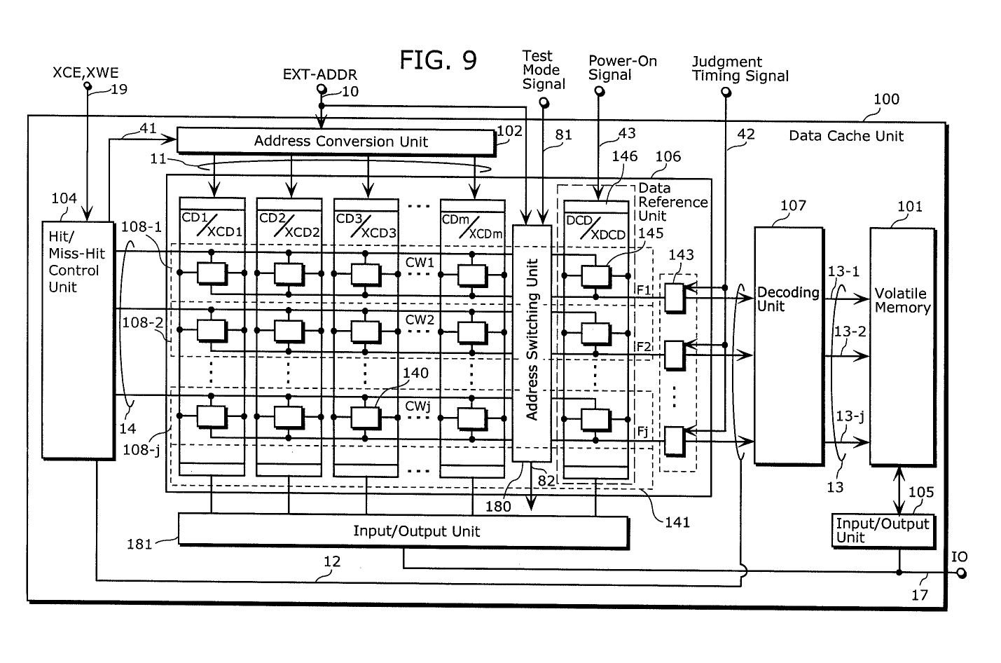

FIG. 9 is a diagram showing the configuration of the data cache unit 100 of the semiconductor memory device, in which the address switching unit 180 is placed between the data holding/comparing element 140 and the data holding/comparing element 145. As shown in FIG. 9, by placing the address switching unit 180 between the data holding/comparing element 140 and the data holding/comparing element 145, it is possible to perform control so that the data holding/comparing element 140 and the data holding/comparing element 145 are separately selected. In other words, the address switching unit 180 controls on the selection of at least one of the data holding/comparing element 140 and the data holding/comparing element 145.

Thus, with the semiconductor memory device according to the embodiment, the address held by the data holding/comparing element 140 selected by the address switching unit 180 and the information held by the data holding/comparing element 145 are updated separately. In other words, it is possible to change only one of the data held by the data holding/comparing element 140 and the data held by the data holding/comparing element 145. Thus, it is possible to easily change the information which is held by the data holding/comparing element 145 and indicates whether or not the address held by the data holding/comparing element 140 is valid, and thereby to improve the efficiency in the examination and estimation of the device.

Since the data holding/comparing element 145 can be separately controlled, it is possible to put an arbitrary data holding unit 108 into a non-usable state. For example, during the delivery inspection of the semiconductor memory devices, a defective data holding unit 108 can be put into the non-usable state. In this case, the defective data holding unit 108 is put into the non-usable state by storing information about defective bits (e.g. defective data holding unit 108) which are detected during the delivery inspection into a non-volatile memory (e.g. a part of the non-volatile memory 200) or into a metal fuse or the like, reading the information about the defective bits when the power of the non-volatile memory 200 is turned on, and controlling the data holding unit selection lines CW1 to CWj of the data holding/comparing element 145 of the defective data holding unit 108. The control performed by the address switching unit 180 is, for example, to perform only the initialization operation for the data holding/comparing element 145 of the defective data holding unit 108, and when the data held by the data holding unit 108 is updated, not to update the data in the data holding/comparing element 145 by not selecting the data holding unit selection lines CW1 to CWj of the data holding/comparing element 145. Thus, the data holding/comparing unit 108 always holds the information indicating that the address held by the corresponding data holding unit 108 is invalid, and the address of the corresponding data holding unit 108 is made invalid.

The hit/miss-hit control unit 104 equipped with the address switching unit 180 may be placed between the data holding/comparing element 140 and the data holding/comparing element 145.

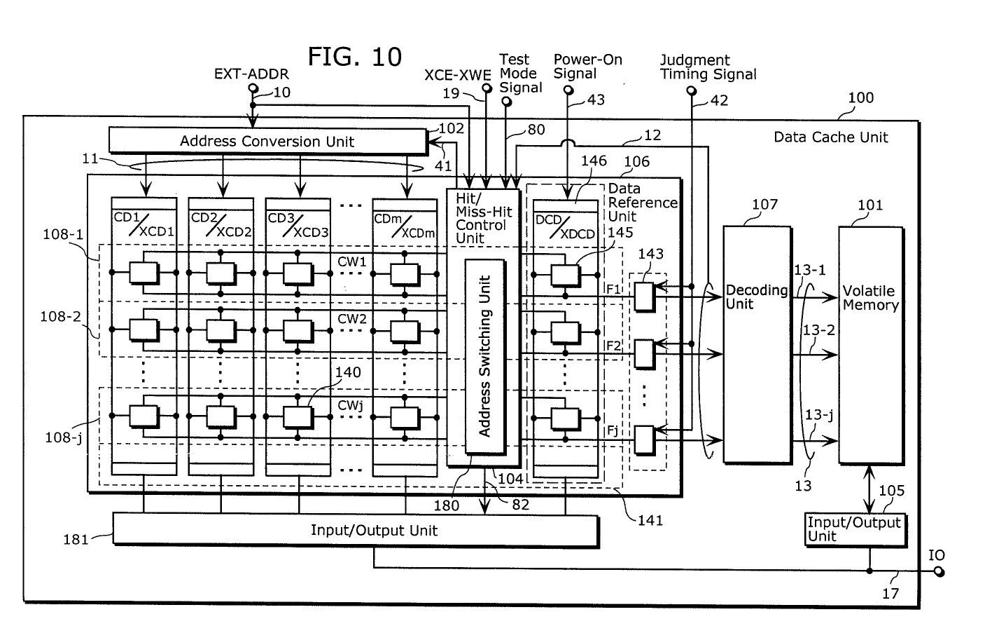

FIG. 10 is a diagram showing the configuration of the data cache unit 100 in the semiconductor memory device in which the hit/miss-hit control unit 104 equipped with the address switching unit 180 is placed between the data holding/comparing element 140 and the data holding/comparing element 145.

As shown in FIG. 10, by placing the hit/miss-hit control unit 104 equipped with the address switching unit 180 between the data holding/comparing element 140 and the data holding/comparing element 145, such a configuration produces the effect of reducing the number of wirings between the blocks owing to the concentration of the functions, in addition to the effect achieved by the semiconductor memory device shown in FIG. 9. It is therefore possible to suppress the extension of the layout size of the semiconductor memory device.

### Third Embodiment

With the semiconductor memory device according to the second embodiment, latch data held by the latch unit 151 might be deconstructed due to the parasitic capacitor in the data reference line CD/XCD unless the driving capacity of the latch unit 151 is sufficient. In contrast, the data holding/comparing element of the semiconductor memory device according to the third embodiment has a data path intended for reading being equipped thereto separately from a data path intended for writing, which prevents the held data from being deconstructed during the read operation in the case of testing.

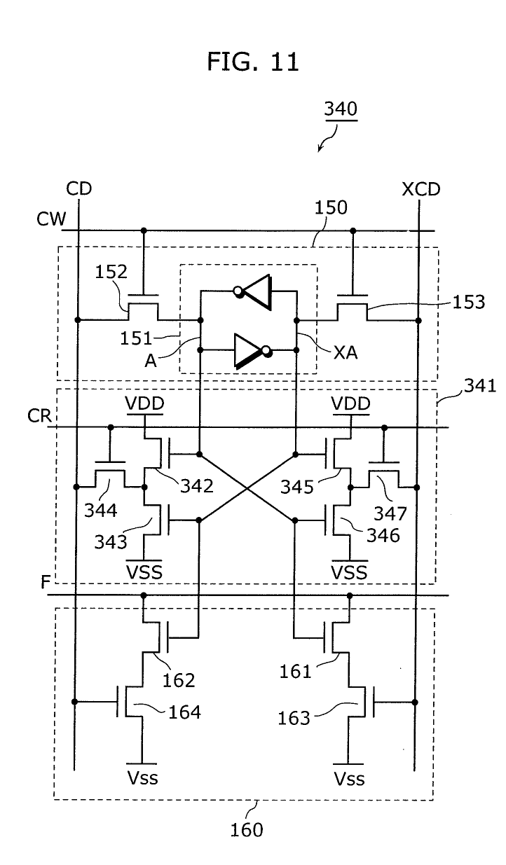

FIG. 11 is a diagram showing the configuration of the data holding/comparing element according to the third embodiment. A data holding/comparing element 340 shown in FIG. 11 includes a read data output unit 341 in addition to the components of the data holding/comparing element 140 shown in FIG. 5. Note that the same referential marks are provided for the same components as shown in FIG. 5, and the detailed description shall be omitted.

The read data output unit 341 includes transistors 342 to 347. The transistors 342 to 347 are, for example, n-type MOSFETs.

In the transistor 342, the gate of the transistor 342 is connected to held data A in the latch unit 151, the drain of the transistor 342 is connected to VDD, and the drain of the transistor 343 is connected to the source of the transistor 342. In the transistor 343, the gate of the transistor 343 is connected to invert held data XA in the latch unit 151, the drain of the transistor 343 is connected to the source of the transistor 342, and the source of the transistor 343 is connected to VSS. With the configuration as described above, the transistors 342 and 343 drive the data held by the latch unit 151 and outputs the data.

The transistor 344 is a pass transistor formed between the data reference line CD, and the transistors 342 and 343. The read selection line CR is connected to the gate of the transistor 344. During the read operation in the case of testing, the level of the selected data holding/comparing element 340 is raised to “H” level.

In the transistor 345, the gate of the transistor 345 is connected to the invert held data XA in the latch unit 151, the drain of the transistor 345 is connected to VDD, and the source of the transistor 345 is connected to the drain of the transistor 346. In the transistor 346, the gate of the transistor 346 is connected to the held data A in the latch unit 151, the drain of the transistor 346 is connected to the source of the transistor 345, and the source of the transistor 346 is connected to VSS. With the configuration as described above, the transistor 345 and the transistor 346 drive the inverting signal of the data held by the latch unit 151, and outputs the data.

The transistor 347 is a pass transistor formed between the data reference line XCD, and the transistors 345 and 346.

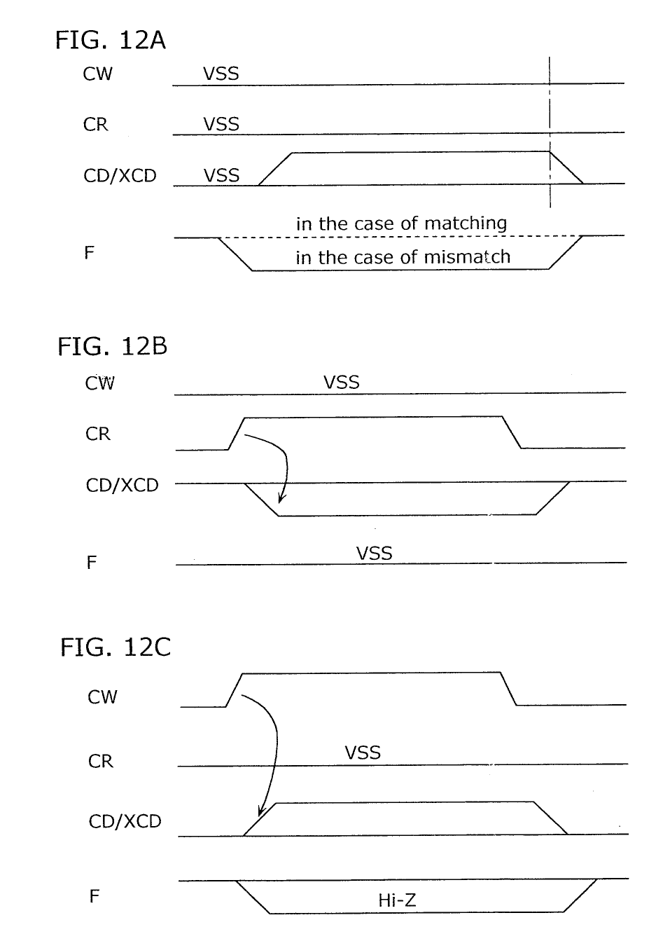

FIGS. 12A, 12B and 12C are timing charts showing the operation of the data holding/comparing element 340 shown in FIG. 11. FIG. 12A is a timing chart showing the operation of the data holding/comparing element 340 during the comparison operation. During the comparison operation, as shown in FIG. 12A, the level of the read selection line CR is at “L” level, and the transistors 344 and 347 are turned off. Aside from this, the data holding/comparing element 340 operates in the same manner as the data holding/comparing element 140 shown in FIG. 5.

FIG. 12B is a timing chart showing the read operation in the case of testing the data holding/comparing element 340. During the read operation in the case of testing, as shown in FIG. 12B, the level of the read selection line CR of the selected data holding/comparing element 340 is raised to “H” level. Owing to this, the transistors 344 and 347 are turned on and the data held in the latch unit 151 is outputted to the data reference line CD/XCD. That is to say that the held data A in the latch unit 151 is outputted to the data reference line CD while the inverse held data XA in the latch unit 151 is outputted to the data reference line XCD.

FIG. 12C shows the data write operation (e.g. write operation or the operation when a miss-hit occurs) performed by the data holding/comparing element 340. During the data write operation, as shown in FIG. 12C, the read selection line CR is at “L” level and the transistors 344 and 347 are turned off. In addition, the data holding unit selection line CW of the selected data holding/comparing element 340 is raised to “H” level. Note that aside from this, the data holding/comparing element 340 operates in the same manner as the data holding/comparing element 140 shown in FIG. 5.

As has been described above, the data holding/comparing element 340 according to the embodiment updates, during the data write operation as shown in FIG. 12C, the held data in the latch unit 151 according to the signal level of the data reference line CD/XCD via the pass transistors 152 and 153. In the read operation in the case of testing as shown in FIG. 12B, the data holding/comparing element 340 outputs the held data in the latch unit 151 to the data reference line CD/XCD via the pass transistors 344 and 347. In other words, the data holding/comparing element 340 includes a writing path which allows conduction when the held data is updated and a reading path which allows conduction when the held data is read.

As described above, the data holding/comparing element 340 according to the embodiment drives the data held by the latch unit 151 using the circuit configured of the transistors 342, 343, 345 and 346, and outputs the data to the data reference line CD/XCD. Thus, during the read operation in the case of testing, the latch unit 151 does not affect the parasitic capacitor of the data reference line CD or XCD. It is therefore possible to prevent the held data in the latch unit 151 from being deconstructed.

Note that the configuration of the read data output unit 341 as shown in FIG. 11 is used in the embodiment. However the circuit configuration is not limited to this and a different circuit may be used providing that the circuit drives the data held by the latch unit 151 and outputs the data. For example, the embodiment describes that the read data output unit 341 is configured by an n-type MOSFET, but it may be configured by CMOS.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is suitable for a semiconductor memory device, and in particular for a semiconductor memory device having a cache memory and a non-volatile memory having a limit on the number of read operations.

What is claimed is:

1. A semiconductor memory device including a non-volatile memory and a volatile memory which holds a part of data held in said non-volatile memory, said semiconductor memory device comprising:
j (j≧1) first holding units, each being operable to hold an address of the data in the non-volatile memory which corresponds to the data held in the volatile memory; and
j second holding units, each corresponding to each of said j first holding units and being operable to hold information indicating whether or not the address held by the corresponding first holding unit is valid.

2. The semiconductor memory device according to claim 1,
wherein each of said second holding units is operable to hold information indicating that the address is invalid when said semiconductor memory device is initialized, and to hold information indicating that the address is valid in the case where an address is written in the corresponding first holding unit.

3. The semiconductor memory device according to claim 2, further comprising:
j first comparing units, each corresponding to each of said first holding units and being operable to compare an externally-inputted address signal with held data held by the corresponding first holding unit, so as to judge whether or not the held data matches the address signal;
j second comparing units, each corresponding to each of said second holding units and each of said first comparing units, and being operable to compare the information held by the corresponding second holding unit with the information indicating that the address is valid, so as to judge whether or not the information match with each other; and
j judging units, each being operable to judge that the address matches the address signal in the case where a result of the comparison made by said first comparing unit indicates that the address signal matches the held data and a result of the comparison made by the corresponding second comparing unit indicates that the information match.

4. The semiconductor memory device according to claim 3, wherein:
each of said first holding units includes m (m≧1) first holding elements, each element holding 1-bit data;
each of said first comparing units includes m first comparing elements, each element comparing between pieces of 1-bit data;
each one of said first holding elements is paired with each one of said first comparing elements so as to form a first holding and comparing element;
each of said second holding units holds 1-bit data;
each of said second comparing units is operable to compare between pieces of 1-bit data;
each one of second holding units is paired with each one of said second comparing units so as to form a second holding and comparing element; and
j×(m+1) first holding and comparing elements and second holding and comparing elements are placed in an array.

5. The semiconductor memory device according to claim 4,
wherein said first holding and comparing element and said second holding and comparing element have a same configuration.

6. The semiconductor memory device according to claim 5,
wherein said m comparing elements included in said first comparing unit and said second comparing unit corresponding to said first comparing unit are connected to a same wiring, and
each of said judging units is operable to judge whether or not the address matches the externally-inputted address signal, based on a signal level of the wiring.

7. The semiconductor memory device according to claim 6,
wherein each of said first comparing elements includes:
a first transistor in which the address is connected to a gate of said first transistor and the wiring is connected to a drain of said first transistor;
a second transistor in which an inverting signal of the address is connected to a gate of said second transistor and the wiring is connected to a drain of said second transistor;
a third transistor in which an inverting signal of the address signal is connected to a gate of said third transistor, a source of said first transistor is connected to a drain of said third transistor, and VSS is connected to a source of said third transistor; and
a fourth transistor in which the address signal is connected to a gate of said fourth transistor, a source of said second transistor is connected to a drain of said fourth transistor, and VSS is connected to a source of said fourth transistor.

8. The semiconductor memory device according to claim 2,
wherein said semiconductor memory device is initialized when power of said device is turned on.

9. The semiconductor memory device according to claim 2,
wherein said semiconductor memory device is initialized when at least one of the non-volatile memory, the volatile memory and said first holding unit is reset.

10. The semiconductor memory device according to claim 1, further comprising:
a selecting unit operable to select at least one of said first holding unit and said second holding unit;
an updating unit operable to update the address held by said first holding unit selected by said selecting unit, and information held by said second holding unit selected by said selecting unit; and
a controlling unit operable to control, based on an externally-inputted address signal, the selection of said first holding unit and said second holding unit performed by said selecting unit.

11. The semiconductor memory device according to claim 10,
wherein said controlling unit is operable to perform control so that said selecting unit separately selects said first holding unit and said second holding unit.

12. The semiconductor memory device according to claim 10, further comprising
a reading unit operable to read the address held by said first holding unit and the information held by said second holding unit,
wherein each of said first holding units and each of said second holding Units respectively include:
a first data path which allows conduction when said updating unit updates the address and the information; and
a second data path which allows conduction when said reading unit reads the address and the information.

13. The semiconductor memory device according to claim 1, further comprising
a first comparing unit operable to compare the address and an externally-inputted address signal so as to judge whether or not the address matches the address signal,
wherein said non-volatile memory includes
a reading unit operable to read the data held by said non-volatile memory,
the read operation performed by said reading unit includes a first sequence and a second sequence which follows the first sequence,
the first sequence is started at the same time when said first comparing unit compares the address and the address signal, and
the second sequence is operated when a result of the comparison indicates that the address matches the address signal, and is not operated when a result of the comparison indicates that the address does not match the address signal.

14. The semiconductor memory device according to claim 13,
wherein the non-volatile memory further includes
a writing unit operable to write data into the non-volatile memory,
the writing by said writing unit includes the first sequence and the second sequence which follows the first sequence,
the first sequence is started at the same time when said first comparing unit compares the address and the address signal, and
the second sequence is operated without waiting for termination of the comparison.

15. The semiconductor memory device according to claim 13,
wherein the first sequence is an operation of selecting a word line of the non-volatile memory, and
the second sequence is an operation of selecting a bit line of the non-volatile memory.

16. The semiconductor memory device according to claim 13, further comprising:
an outputting unit which has a tri-state output to output read data which is read from the non-volatile memory; and
an inputting unit operable to input, to the volatile memory, the data outputted by said outputting unit,
wherein control on a timing at which an output state of said outputting unit shifts from a Hi-Z output to an output of the read data and control on a timing at which said inputting unit is started up are performed based on a same signal.

17. A reading method used in a semiconductor memory device including a non-volatile memory and a volatile memory which holds a part of data held in the non-volatile memory and an address corresponding to the data, said method comprising:
comparing an externally-inputted address signal and the address so as to judge whether or not the address signal matches the address;
starting reading the data held in the non-volatile memory at the same time when said comparing is performed; and
reading the data held in the non-volatile memory in the case where a result of said comparing indicates that the address signal does not match the address, and not reading the data in the case where a result of said comparing indicates that the address signal matches the address.
